(19) United States
(12) Patent Application Publication
(10) Pub. No.: US 2011/0157839 A1
(43) Pub. Date: Jun. 30, 2011

(54) ELECTRONIC DEVICE, FILTERING MODULE THEREOF AND METHOD FOR REDUCING COMMON MODE NOISE

(76) Inventors: Chung-Won Shu, Taipei City (TW); Chih-Heng Chiu, Taipei City (TW); Din-Ji Tzou, Taipei City (TW); Chung-Wen Huang, Taipei County (TW)

(21) Appl. No.: 12/694,284

(22) Filed: Jan. 27, 2010

(30) Foreign Application Priority Data
Dec. 31, 2009 (TW) 098146595

(51) Int. Cl. H05K 7/00; H03H 7/00

(52) U.S. Cl. 361/748; 333/167

(57) ABSTRACT

A filtering module includes a circuit board, a connector, a core and a plurality of coils. The connector and the core are disposed on the circuit board. The coils wind around the core and are electrically connected to the connector.

### BACKGROUND OF THE INVENTION

1. Field of the Invention

The preferred embodiment relates to a filtering module and, more particularly, to a filtering module for filtering common mode noise.

2. Description of the Prior Art

Electromagnetic interference (EMI) is a physical phenomenon filled up everywhere in daily life. In general, the noise of electromagnetic interference can be divided into differential mode noise and common mode noise. At present, most of electronic devices, which need to use flat printed cable (FPC) or flat flexible cable (FFC) to connect electronic components, usually suffer problems of common mode noise. If the common mode noise is too large, EMI test of electronic devices will fail.

Referring to FIG. 1, FIG. 1 is a schematic diagram illustrating a conventional core 10 for filtering common mode noise. As shown in FIG. 1, an electronic device (not shown) generally comprises a main board 12, a connector 14 disposed on the main board 12, and a chip 16 for signal processing. The connector 14 is electrically connected to the chip 16 via circuit layout of the main board 12. Other electronic components of the electronic devices are electrically connected to the connector 14 via an FPC or FFC 18. A core 10 made of ferrite is usually set on the FPC or FFC 18 to filter common mode noise, as shown in FIG. 1.

### SUMMARY OF THE INVENTION

The preferred embodiment is to provide a filtering module for filtering common mode noise on an electronic device.

According to one embodiment, a filtering module comprises a circuit board, a connector, a core and a plurality of coils. The connector and the core are disposed on the circuit board. The plurality of coils winds around the core and is electrically connected to the connector.

According to another embodiment, an electronic device comprises a main board, a chip, a filtering module, an electronic component and a cable. The filtering module comprises a circuit board, a connector, a core and a plurality of coils. The chip and the filtering module are disposed on the main board. The connector and the core are disposed on the circuit board. The connector is electrically connected to the chip. The plurality of coils winds around the core and is electrically connected to the connector. The cable is electrically connected to the connector and the electronic component.

The filtering module of the preferred embodiment can be disposed on the main board of the electronic device by surface mount technology (SMT).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a conventional core for filtering common mode noise.

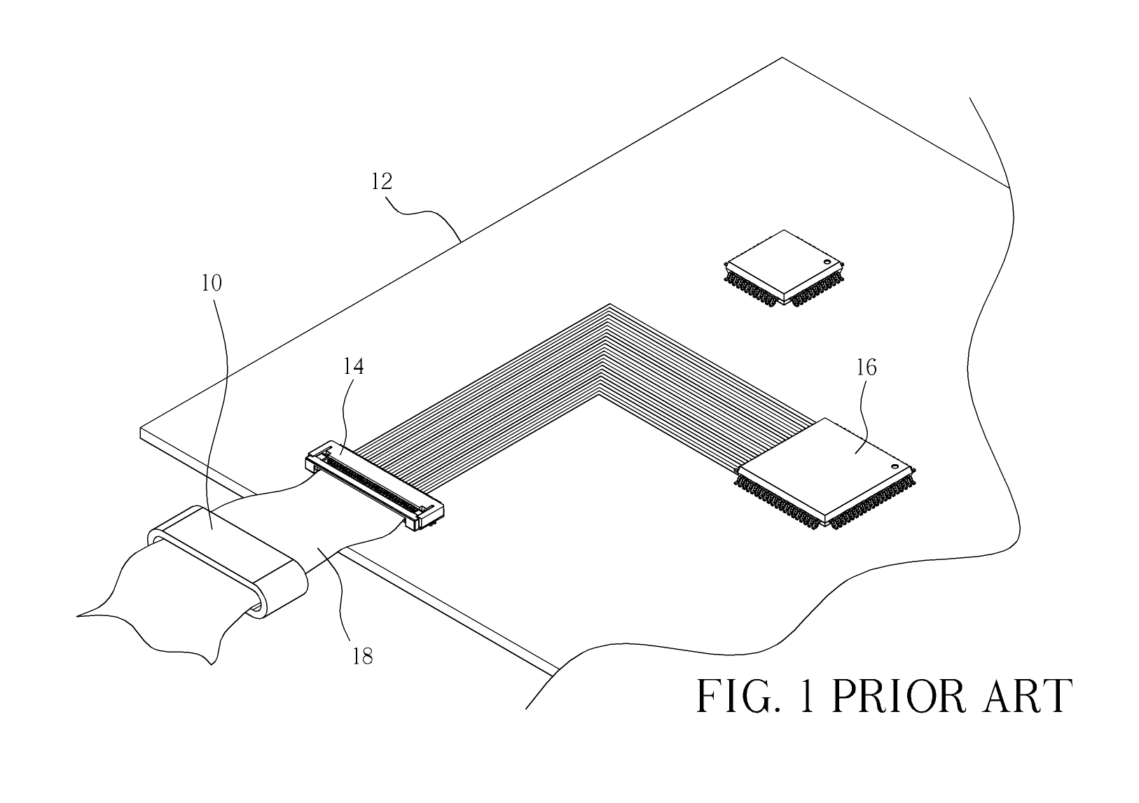

FIG. 2 is a perspective view illustrating the electronic device according to one preferred embodiment.

FIG. 3 is a schematic diagram illustrating parts of components of the electronic device shown in FIG. 2.

FIG. 4 is an enlarged view illustrating the filtering module shown in FIG. 3.

FIG. 5 is a flow chart of a method for filtering common mode noise according to another preferred embodiment.

### DETAILED DESCRIPTION

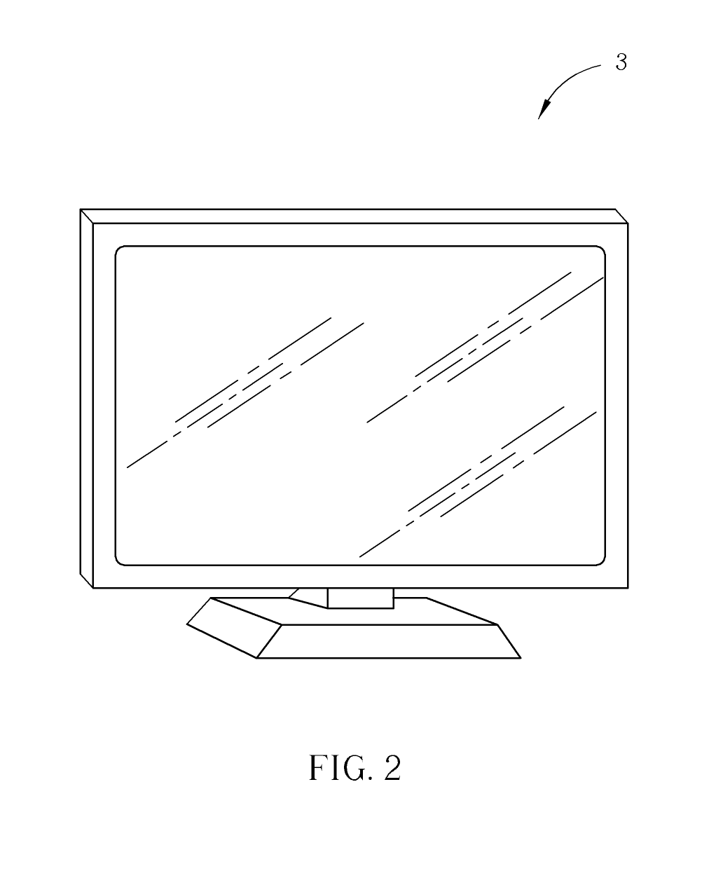

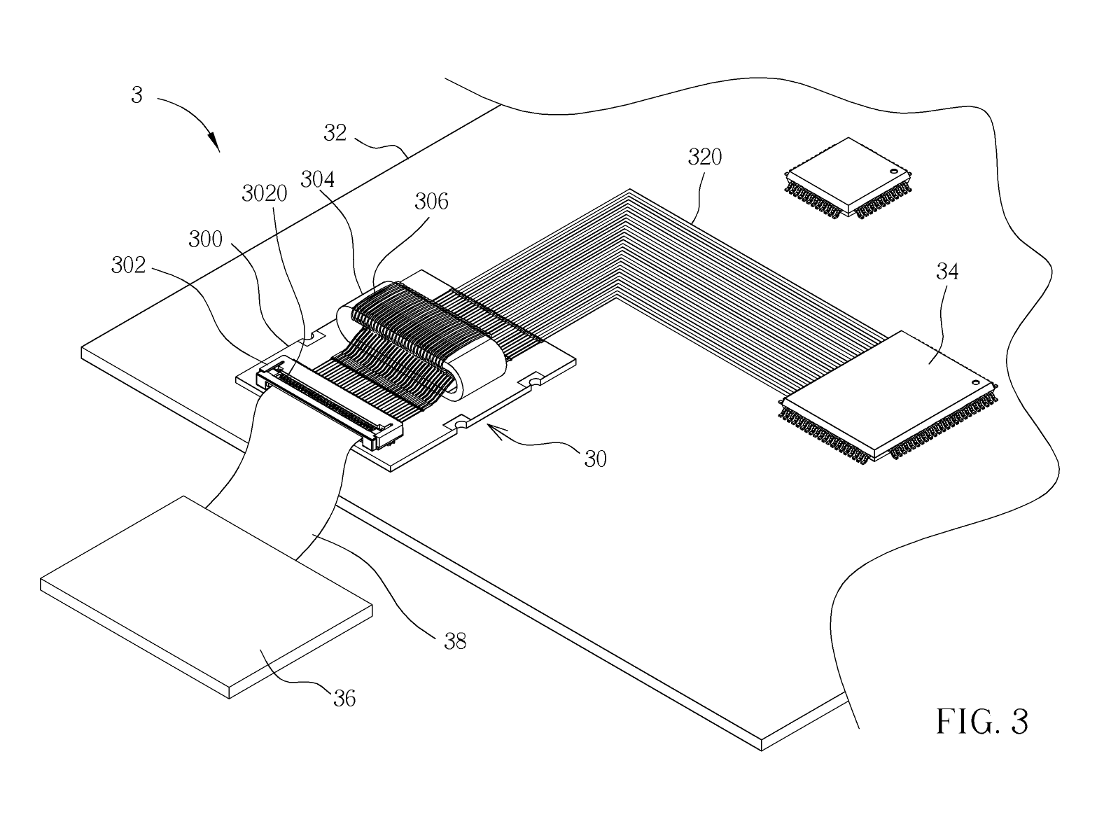

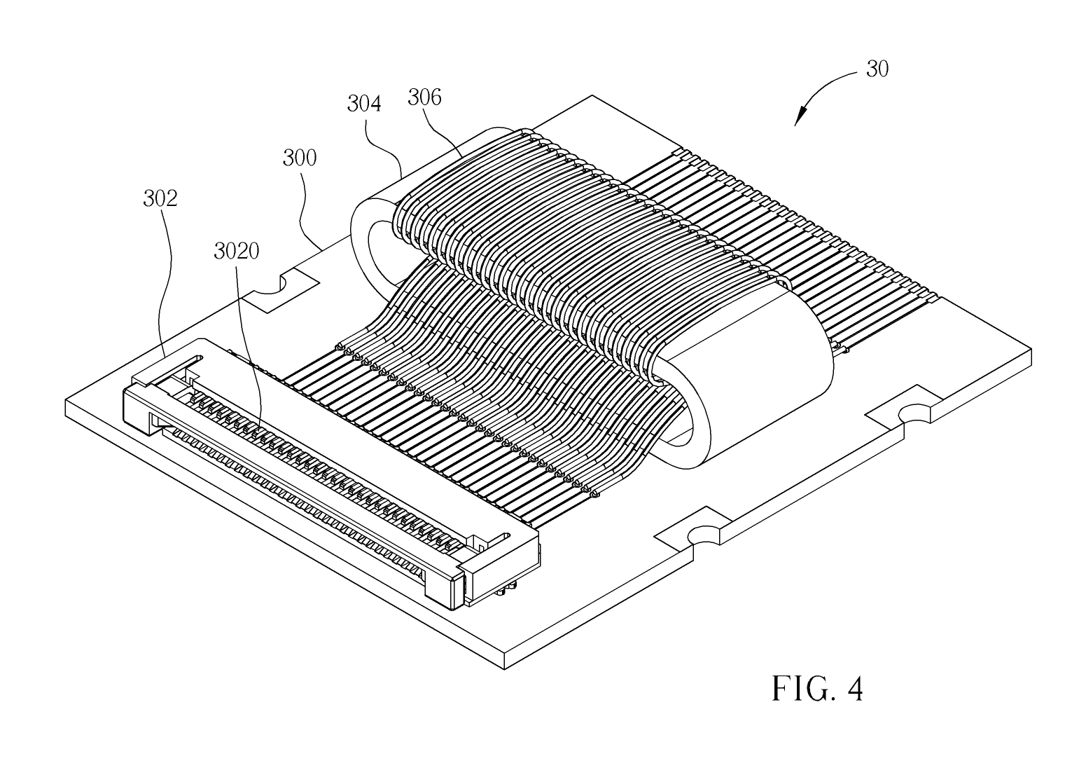

Referring to FIG. 2 to FIG. 4, FIG. 2 is a perspective view illustrating an electronic device 3 according to one preferred embodiment. FIG. 3 is a schematic diagram illustrating parts of components of the electronic device 3 shown in FIG. 2. FIG. 4 is an enlarged view illustrating the filtering module 30 shown in FIG. 3. In this embodiment, the electronic device 3 may be, but not limited to, a flat display device such as liquid crystal television, plasma television, digital photo frame, and so on. As shown in FIG. 3, an electronic device 3 comprises a filtering module 30, a main board 32, a chip 34, an electronic component 36 and a cable 38. If the electronic device 3 is a flat display device, the electronic component 36 can be, but not limited to, a display panel. Furthermore, the cable 38 can be an FPC or FFC. The main board 32 comprises a circuit layout 320, and a chip 34 disposed on the main board 32. The chip 34 is electrically connected to the circuit layout 320 for signal processing.

As shown in FIG. 3 and FIG. 4, the filtering module 30 comprises a circuit board 300, a connector 302, a core 304 and a plurality of coils 306. In this embodiment, the core 304 may be made of ferrite. The circuit board 300 is disposed on the main board 32. The connector 302 and the core 304 are disposed on the circuit board 300. The plurality of coils 306 winds around the core 304 and is electrically connected to the connector 302. Moreover, the connector 302 has a plurality of pins 3020, and each of the plurality of pins 3020 is electrically connected to one of the plurality of coils 306 respectively. The plurality of coils 306 is electrically connected to the chip 34 via the circuit layout 320 of the main board 32. The cable 38 is electrically connected to the connector 302 of the filtering module 30 and the electronic device 36.

After common mode noise passing through the core 304 of the filtering module 30, common mode noise will be reduced from the cable 38 to the electronic component 36. Such that the electronic device 3 can pass EMI test. In this embodiment, a number of turns of each coil 306 wound around the core 304 is equal to each other, but it is not limited to that. Moreover, in the preferred embodiment, the number of turns of each coil 306 wound around the core 304 can be equal to the number of signal lines according to the practical signal outputs. In other words, the preferred embodiment can utilize one single core 304 to filter common mode noise for a row of signal lines.

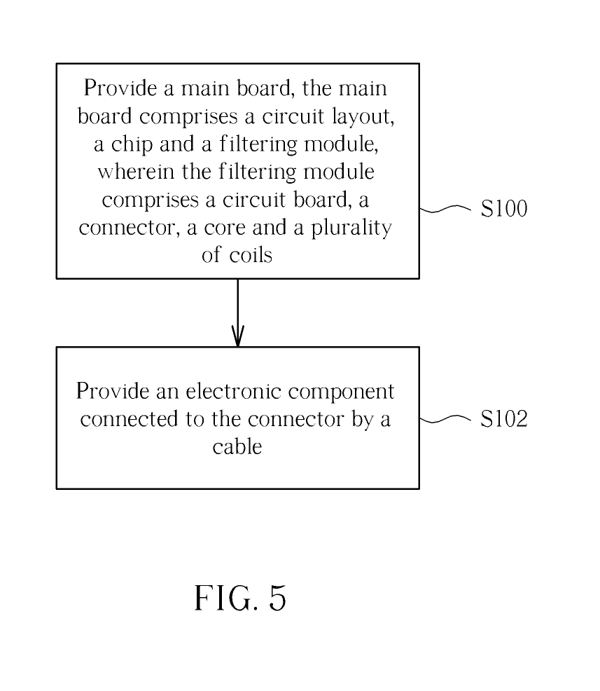

Referring to FIG. 5, FIG. 5 is a flow chart of a method for reducing common mode noise according to another preferred embodiment. Referring to FIG. 2 to FIG. 4 along with the aforesaid electronic device 3, a method for reducing common mode noise comprises the following steps. In the beginning, step S100 is performed to provide a main board 32. The main board 32 comprises a circuit layout 320, a chip 34 and a filtering module 30, wherein the filtering module 30 comprises a circuit board 300, a connector 302, a core 304 and a plurality of coils 306. Afterward, step S102 is performed to provide an electronic component 36 connected to the connector 302 by a cable 38. The principle of the aforesaid components is mentioned in the above, so it will not be depicted herein.

Those skilled in the art will readily observe that numerous modifications and alterations of the device and method may be made while retaining the teachings of the invention.

What is claimed is:

1. A filtering module comprising:
a circuit board;
a connector disposed on the circuit board;
a core disposed on the circuit board; and
a plurality of coils winding around the core and being electrically connected to the connector.

2. The filtering module of claim 1, wherein the core is made of ferrite.

3. The filtering module of claim 1, wherein the connector has a plurality of pins, and each of the plurality of pins is electrically connected to one of the plurality of coils respectively.

4. The filtering module of claim 1, wherein a number of turns of each coil wound around the core is equal to each other.

5. An electronic device comprising:
a main board comprising a circuit layout formed thereon;
a chip disposed on the main board and electrically connected to the circuit layout;
a filtering module comprising:
a circuit board disposed on the main board;
a connector disposed on the circuit board;
a core disposed on the circuit board; and
a plurality of coils winding around the core and being electrically connected to the connector, the plurality of coils being further electrically connected to the chip via the circuit layout;
an electronic component; and
a cable electrically connected to the connector and the electronic component.

6. The electronic device of claim 5, wherein the core is made of ferrite.

7. The electronic device of claim 5, wherein the connector has a plurality of pins, and each of the plurality of pins is electrically connected to one of the plurality of coils respectively.

8. The electronic device of claim 5, wherein a number of turns of each coil winding around the core is equal to each other.

9. The electronic device of claim 5, wherein the electronic component is a display panel.

10. The electronic device of claim 5, wherein the cable is a flat printed cable or a flat flexible cable.

11. A method for reducing common mode noise comprising steps of:
providing a main board, the main board comprising a circuit layout, a chip and a filtering module, wherein the filtering module comprises:
a circuit board disposed on the main board;
a connector disposed on the circuit board;
a core disposed on the circuit board; and
a plurality of coils winding around the core and being electrically connected to the connector, the plurality of coils being further electrically connected to the chip via the circuit layout; and
providing an electronic component connected to the connector by a cable.

12. The method of claim 11, wherein the core is made of ferrite.

13. The method of claim 11, wherein the electronic component is a display panel.

14. The method of claim 11, wherein a number of turns of each coil wound around the core is equal to each other.
